(19) United States
(12) Patent Application Publication
(10) Pub. No.: US 2002/0150155 A1
(43) Pub. Date: Oct. 17, 2002

(54) Convergence speed, lowering the excess noise and power consumption of equalizers

(76) Inventors: Itzhak Florentin, M.P. Misgav (IL); Pranesh Sinha, San Diego, CA (US); William Farnbach, San Diego, CA (US); Itzhak Gurantz, San Diego, CA (US)

Correspondence Address: AKIN, GUMP, STRAUSS, HAUER & FELD, 711 LOUISIANA STREET, SUITE 1900 SOUTH, HOUSTON, TX, 77002, US

(21) Appl. No.: 09/793,660

(22) Filed: Feb. 26, 2001

(51) Int. Cl. H03H 7/30

(52) U.S. Cl. 375/233; 375/316

(57) ABSTRACT

An equalizer for equalizing channel multi-path distortion includes digital filters. To improve the convergence speed and tracking ability of the equalizer while lowering noise and power consumption, the digital filters are divided into sections. Various parameters of the sections, such as step-size, shutdown and update rates can be controlled. Control of the various parameters can be realized either in software on an embedded or external processor or by dedicated hardware.

### BACKGROUND

1. Field of the Invention

The present invention relates to an apparatus for communication devices, in particular an equalizer for use in a communication system.

2. Description of the Related Art

Data transmission through any form of channel rarely operates in an ideal state predicted by theory. To compensate for the distortion caused by the transmission channel, equalizers have been used to facilitate data reception. Equalizers, which date back to the use of loading coils to improve the characteristics of twisted-pair telephone cables for voice transmission, become even more necessary in high-speed data transmission for reducing the intersymbol interference (ISI) introduced by the channel.

Broadcasting digital TV signals over the air experiences significant multi-path distortion resulting in ISI. The digital signals travel through the atmosphere and are reflected by various objects such as buildings, resulting in multiple copies of the transmitted signals. Thus, the signals received by a receiver through the air typically contain a combination of the multiple copies of the transmitted signals. An equalizer is typically employed in a receiver to cancel out these multiple signals, also known as echoes.

One type of equalizer used for digital TV terrestrial transmission is known as a decision-feedback equalizer (DFE). A DFE has a feedforward filter and a feedback filter. A decision device is included in the feedback path. The feedforward filter processes the received signals by combining multiple copies of the received signals together. Each copy of the received signals corresponds to a “tap” of the feedforward filter. The copy of the received signals corresponding to each tap is delayed in time by a “tap delay time,” multiplied by a tap coefficient and the multiplication results added together to form the feedforward filter output. Thus, the feedforward filter performs a cascade of a noise-whitening filter, a matched filter, and a linear filter, which mitigates a type of ISI called pre-cursor ISI. The feedback filter uses decisions from the decision device to cancel another type of ISI called post-cursor ISI.

In a conventional digital communication system, a digital signal typically includes a main signal which is directly transmitted to a receiver, the post-cursor ISI signal, which is reflected by a predetermined reflective matter and then arrives later than the main signal, and a pre-cursor ISI signal, which arrives earlier than the main signal under certain conditions, for example, atmospheric conditions. Therefore, the receiver receives a signal including the main signal, a pre-cursor ISI signal, and a post-cursor ISI signal.

The DFE typically should perform several functions. The DFE needs to estimate the channel and then use these estimates to cancel the echoes. The equalizer can gain knowledge of the channel characteristics without the aid of dedicated channel estimation circuitry in a number of ways. A simple way is to employ a predefined “training” sequence of symbols in predefined places along the data stream. A synchronization device captures the output of the equalizer at these periods, and by comparing this data to the known transmitted data, it produces an “error” signal, which is used to adjust the equalizer coefficients.

Another method, known as decision directed (DD) training, can be used when the equalizer reaches a point in which a good estimation of a transmitted symbol can be produced at the equalizer output. Since the transmitted symbol is one of a known set of symbols (Alphabet), a decision is made as to which symbol was transmitted. The error between this decision and the output of the equalizer is used to adapt the equalizer coefficients.

Another method of adaptation, known as “blind” training, may be applied even when the reliability of decisions at the output of the equalizer is low. In this method, the equalizer tries to match its output statistics with the known statistics of the transmitted symbols. Because this method is based on long-term statistics, it is slower than the other two methods which are based on the individual values of the symbols.

The DFE is essentially an adaptive digital filter. In systems using an adaptive equalizer, a method should provide for adapting the filter's response to adequately compensate for channel distortions. Several algorithms are available for adapting the filter coefficients and thereby the filter's response. One commonly used method employs a least mean squares (LMS) algorithm. There are many variations of the LMS algorithm. In one algorithm, by varying the coefficient values as a function of an error signal (E), the equalizer output signal is forced to approximately equal a reference data sequence. This error signal E is formed by subtracting the equalizer output signal from the reference data sequence. As the error signal E approaches zero, the equalizer approaches convergence, whereby the equalizer output signal and the reference data sequence are approximately equal.

In deploying an alternative LMS algorithm, each tap coefficient is adapted by adding to it a quantity that is proportional to the multiplication of the error signal with the data component at the tap. The proportion factor is known as a step-size. The step-size effects the speed of the convergence of the equalizer and its ability to adapt to changing channel conditions. Greater step-sizes typically yield better dynamic performance but also greater excess noise and could possibly result in divergence rather than convergence. The value of the step-size is upper-bounded by the channel conditions and by the adaptation method used, e.g., a training sequence, DD or blind. In terrestrial digital transmission, the channel may consist of numerous echoes with various delays that may span 300 or more symbols or 30 μs. To equalize such a channel, a very long equalizer is needed. Consequently, the usable step-size for the above adaptation methods become very low and the equalizer becomes slow. One way to improve the convergence speed and channel tracking is done by the use of Kalman filtering. However, the use of Kalman filtering is far more computationally intensive, thus requiring greater processing power.

### SUMMARY OF THE INVENTION

Briefly, an equalizer for terrestrial data transmission, such as digital television or High Definition Television (HDTV), is disclosed. The equalizer can be incorporated into televisions, VCRs, or other apparatuses for receiving terrestrial data. The equalizer includes various digital filters. The digital filters are divided into filter sections so that certain echoes can be cancelled. The cancellation of the certain echoes are done by controlling various parameters of the digital filters. Such parameters include step-size, update rate, and shutdown.

The filter sections typically includes many taps. To optimize the digital filter in a dynamic environment, the coefficients for each of the taps for each filter section may be adjusted. The coefficients are typically adjusted by using an algorithm, such as a least means square (LMS) algorithm. Each tap coefficient is adapted by adding to it a quantity that is proportional to the multiplication of the error signal with the conjugate of the data component at the tap. The proportion factor is known as a step-size. The step-size generally determines the speed of convergence of the equalizer and its ability to adapt to changing channel conditions. The use of a large step-size may result in non-convergence. The use of a small step-size may possibly result in slow convergence and inadequate response to variations in channel conditions.

The step-size can be controlled by monitoring the coefficient's trend for a particular filter section. A constant average coefficient value indicates a constant echo structure for the filter section for which the step-size may be kept low. Changes of the average coefficient's value indicate dynamic echoes and a large step-size may apply. Thus, dynamic echoes are tracked faster than the static ones, but the equivalent step-size for the whole equalizer is still kept at a value that enables convergence and relatively low excess noise.

Each filter section can be shut down using a control section. By shutting down a filter section(s), the equalizer may preserve power and lower the steady state excess noise. To conserve power and reduce steady state excess noise, a filter section(s) in which the equalizer taps have small coefficient values is disabled. The small tap coefficient value indicates that there is very little multi-path to equalize. Thus, shutting down the filter section by disabling its circuitry preserves power and lowers the steady state excess noise. Even with the filter section disabled, the coefficients of the taps continue to be updated at a very low rate and if the coefficient values pass a threshold the filter section becomes active again.

Typically, a tap's coefficient is updated once every K clocks. For constant taps, as determined by the algorithm of the step-size control, and for shutdown taps, the update rate can be reduced significantly, thus lowering excess noise and power consumption.

### BRIEF DESCRIPTION OF THE DRAWINGS

A better understanding of the present invention can be obtained when the following detailed description of the preferred embodiment is considered in conjunction with the following drawings, in which:

FIG. 1 is a block diagram of a communication system;

FIG. 2 is a linear transversal equalizer;

FIG. 3 is a block diagram of a decision-feedback equalizer (DFE);

FIG. 4 is a block diagram of a equalizer according to the present invention;

FIG. 5 is a block diagram of a single tap of a filter according to the present invention;

FIG. 6 is a block diagram of a single tap of an alternative filter according to the present invention;

FIG. 7 is a flow chart for disabling a filter section according to the present invention;

FIG. 8 is a flow chart for revising an update rate for a particular filter section using an LMS algorithm according to the present invention; and

FIG. 9 is a flow chart for revising a step size for a particular filter section using an LMS algorithm according to the present invention.

### DETAILED DESCRIPTION OF PREFERRED EMBODIMENT

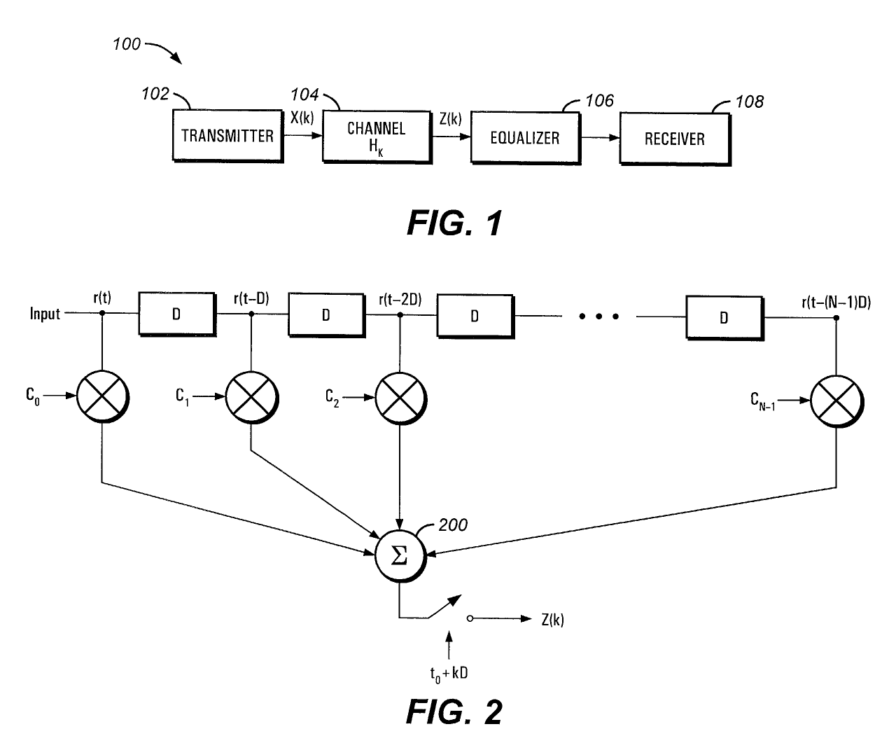

Turning now to the drawings, FIG. 1 illustrates a system 100 for the transmission of digital data via a channel. The digital data can be HDTV, for example, and the channel media can be air, for example. The signal to be transmitted is represented by X(k), where X =0, 1, 2 . . . represents discrete time variables. The signal X(k) generally is modulated onto a sine wave carrier by a transmitter 102.

The signal X(k) is then transmitted through a channel represented by box 104. The channel impulse response at the time k is represented by the vector

$${H}_{k} = {[ \begin{matrix}{h}_{1} \\ {h}_{2} \\ ⋮ \\ {h}_{n}\end{matrix} ]}_{k}$$

Thus, the signal Z(k) arriving at a receiver 106 may be degraded. The receiver 106 includes a demodulator 108, an equalizer 110, and a decoder 112. One source of degradation results from the slowly changing impulse response Hk of the channel 104. The received signal is demodulated by the demodulator 108, and the equalizer 110 processes the arriving signal values y(k) so that the signal to a decoder 112 closely represents the encoded signal that was modulated and transmitted from the transmitter 102.

FIG. 2 is one type of equalizer known as a linear transversal equalizer. Current and past values r(t−nD) of a received signal r(t) are linearly weighted by coefficients C_{N} and summed at a summer 200 to produce an output Z(k). Samples of the received signal r(t) at a symbol rate k are typically stored in a digital shift register and the equalizer output samples (sums of products) Z(t₀+kD) or Z(k) are computed, once per symbol, according to

$$Z ( k ) = {\sum }_{n = 0}^{N - 1} {C}_{N} r ( {t}_{0} + kD - nt )$$

where N is a number of equalizer coefficients C and t₀ denotes sample timing.

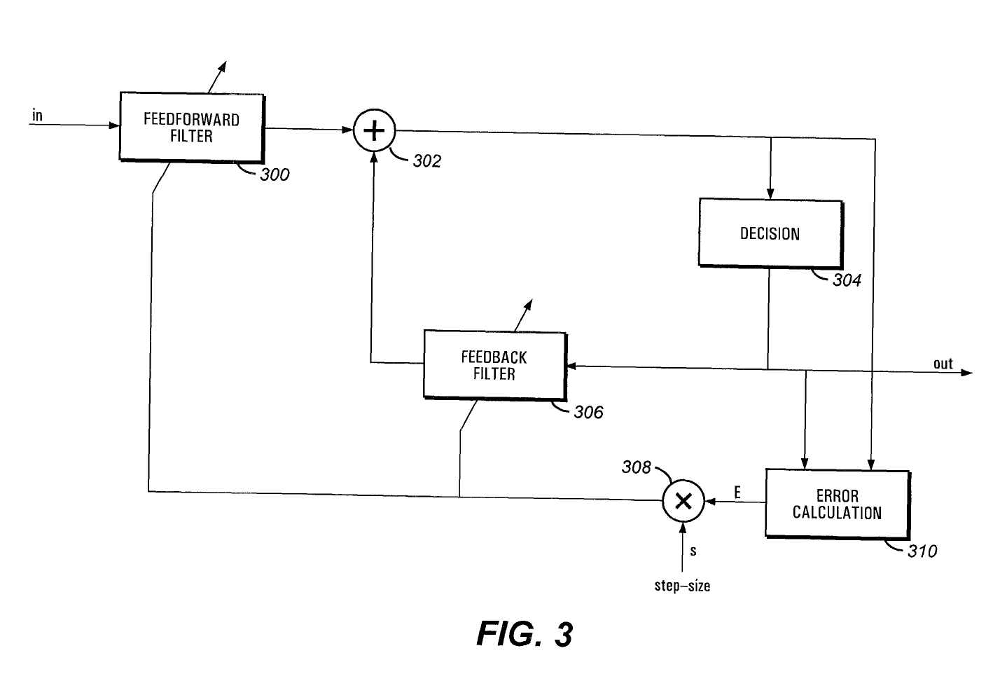

Another type of equalizer is a decision feedback equalizer (DFE). FIG. 3 is a block diagram of a DFE. A DFE generally consists of two filters, such as a feedforward filter 300 and a feedback filter 306. The feedforward filter 300 is generally a fractionally-spaced or symbol-spaced finite impulse response (FIR) filter with adjustable tap coefficients. The feedforward filter 300 is fed with the demodulated signal sampled at some rate that is a multiple of the symbol rate, for example, at rate 2/T. The feedback filter 306 can also be implemented as an FIR filter with symbol-spaced taps having adjustable coefficients. The input to the feedback filter 306 is typically the set of previously detected symbols from the output of the decision device 304. The decision device 304 may determine which of the possible transmitted symbols is closest to its input signal. The output of the feedback filter 306 is subtracted from the output of the feedforward filter 300 at an adder 302 to form the input to the decision 304. The feedforward filter 300 generally acts like the linear transversal equalizer of FIG. 2. Decisions made on the equalizer signal are fed back via a feedback filter, typically a second transversal filter. Generally, if the value of the symbols already detected are known (typically, past decisions are assumed to be correct), then the ISI contributed by these symbols can be cancelled, by subtracting past symbol values with appropriate weighting from the equalizer output. The coefficients of the feedforward filter 300 and the feedback filter 306 can be adjusted based on a step-size s multiplied by an error E. The error E is the difference between the post decision symbol (assumed to be the transmitted symbol) and the pre decision value.

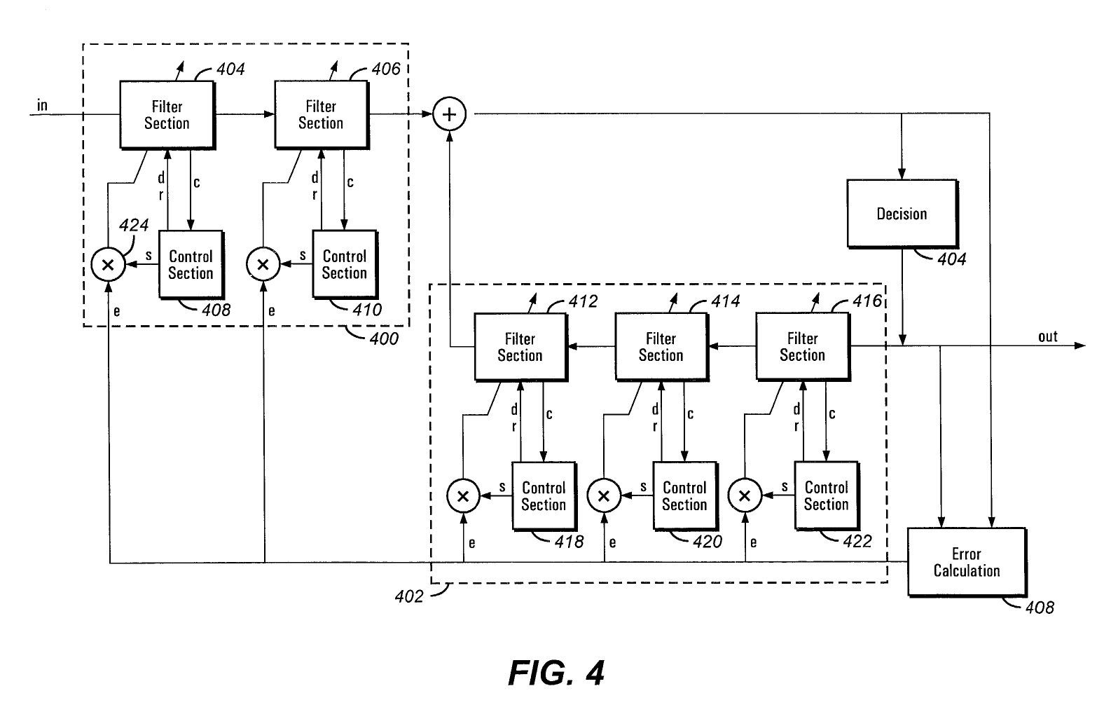

FIG. 4 is a DFE implemented using techniques of the present invention. The DFE can be incorporated into a digital receiver, such as, for example, a television or VCR. The DFE can also be incorporated into a VSB receiver used in one embodiment for High Definition Television (HDTV) reception via an antenna. The reception of HDTV can be hampered by echoes as a result of obstacles, such as buildings, cars, etc. A way of improving the convergence speed and tracking ability of the DFE while lowering the excess noise and power consumption is achieved by dividing the filters of the equalizer into sections and for each section controlling several parameters such as step size s of the LMS algorithm, shut down ability of the sections, and update rate r of the LMS algorithm.

A feedforward filter 400 is divided into filter sections, and in one embodiment shown in FIG. 4, there are two filter sections 404 and 406. Control sections 408 and 410 are coupled to filter sections 404 and 406, respectively.

The feedback filter 402 is also divided into sections as shown in FIG. 4. In one embodiment, the feedback filter 402 has three filter sections 412, 414 and 416. Control sections 418, 420 and 422 are coupled to the filter sections 412, 414 and 416, respectively. Note, one skilled in the art could recognize that the feedforward filter 400 and the feedback filter 402 can include any number of filter sections. The different filter sections generally cancel the many echoes, typically allowing the main signal to pass. With appropriate tap coefficients within each filter section, each filter section can cancel a particular ISI, either pre-cursor or post-cursor. For example, the first filter section 404, can cancel pre-cursor ISI that range in time from 1 to 2 μs. The second filter section 406 can cancel pre-cursor ISI of 0 μs to 7 μs. The remaining filter sections can cancel other pre-cursor ISI.

In one embodiment, the feedback filter 402 cancels post-cursor ISI of 0 to 25 μs. Furthermore, the feedback filter 402 includes eighteen (18) filter sections in one embodiment. Each of the eighteen (18) filter sections can cancel particular post-cursor ISI in time. For example, the first filter section 412 can cancel post-cursor ISI that range in time from 0 to 1 μs. The remaining filter sections can cancel other post-cursor ISI. For example, the VSB receiver used for HDTV usually processes pre-cursor ISI typically lasting 3 to 4 μs and post-cursor ISI typically lasting 25 μs.

The control sections reads the tap coefficients of each tap in its filter section. Small tap coefficient values indicate that there is little signal to equalize. Thus, the tap generally contributes little to the equalization function, but still consumes power and contributes to excess noise. Shutting down the particular filter section by disabling its circuitry preserves power and lowers excess noise. For example, if filter section 404 cancels pre-cursor ISI that are 0 to 1 μs, and after iterations in the LMS algorithm, tap coefficients for the filter section 404 are small, the control section 408 would detect the small coefficient values for the taps of the filter section 404, and can disable the filter section 404. The control sections 408, 410, 418, 420 and 422 can be controlled either in software on an embedded or external processor, by dedicated hardware, e.g. a microcontroller, or using other techniques. Therefore, by disabling a particular filter section, the DFE preserves power and also reduces excess noise.

The step-size s can be controlled by the control section. The step-size can be controlled by monitoring the coefficient trends in the filter section. A constant average value indicates a constant echo structure for this filter section for which the step-size s may be kept low. Changes of the average coefficient value indicates dynamic echoes and a larger step-size may be used.

For example, the control section 408 detects the coefficient C from the filter section 404. If the coefficient C remains relatively constant, the control section 408 provides a small step-size s to a multiplier 424. Likewise, the step-size s for the other filter section in the feedforward filter 400 and the feedback filter 402 may be kept low if the coefficients C for the respective filter section are constant. Thus, less excess noise is generated by sections that equalize stationary echos.

The coefficient C value can be updated as defined by an update rate r, once every k clocks. For relatively constant C values (that may be determined by the algorithm of the step-size control), the update rate r can be reduced, thus lowering the power consumption by reducing the amount of calculations needed for that section. For example, if the coefficients C values of the filter section 404 are constant, the control section 408 will detect that the coefficients C values are constant and reduce the update rate r of the coefficients C values of the filter section 404. If the coefficients C values fluctuates, the control section 408 can increase the update rate r of the coefficient C values of the filter section 404. Thus, again, processing power and excess noise are reduced for those coefficients C that are relatively constant.

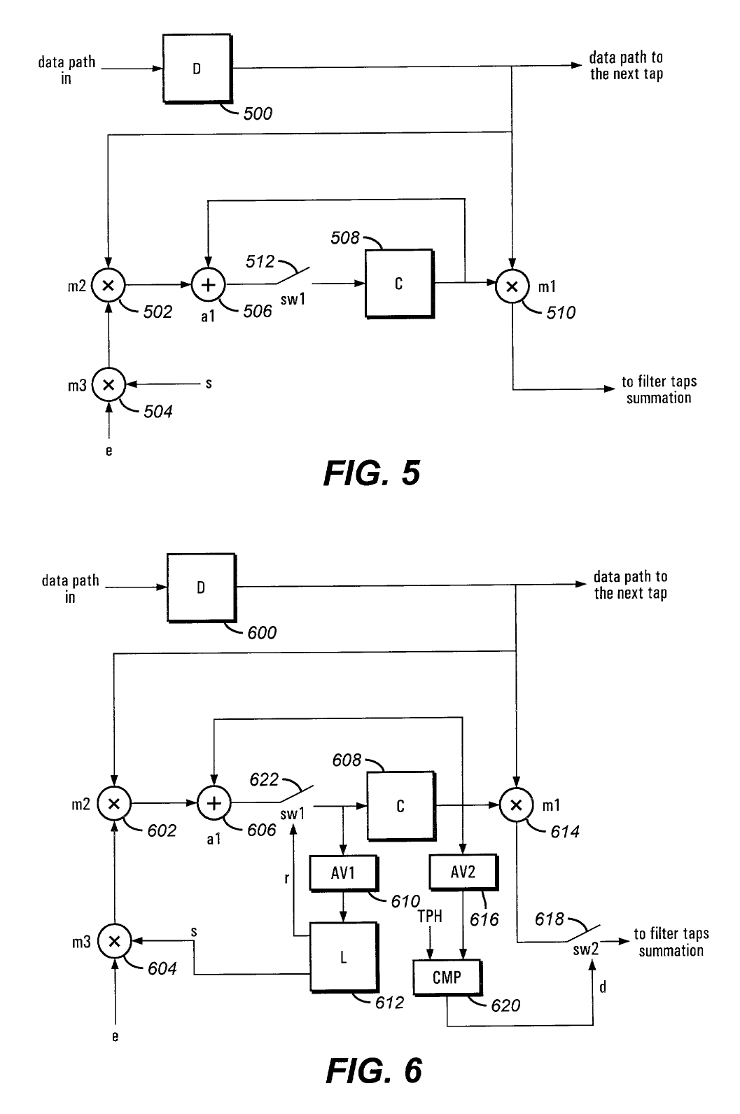

FIG. 5 is a block diagram of a single tap of a filter section of FIG. 4. Data is inputted into delay register 500 of interval D seconds, where D is the symbol interval of the input data stream. A step-size s and an error e are multiplied at a multiplier 504. The resultant of the multiplier 504 is inputted into a multiplier 502 to be multiplied with the output of the delay logic 500. The resultant of the multiplier 502 is added with a tap coefficient C at adder 506. The output of the adder 506 is the updated tap coefficient C if a switch 512 is closed. If the switch 512 is open, the multipliers 502 and 504, and adder 506 are not used. The tap coefficient C is multiplied with the output of the register 500 at multiplier 510. The resultant of the multiplier 510 is summed with other taps at another adder (not shown) to produce the filter output. The switch 512 can be controlled by the control section of FIG. 3. In addition, the step-size s can originate from the control section of FIG. 3. Thus, if it is desirable to disable the adaptation of the filter section, the switch 512 is opened and if it is desirable to disable the filter tap, a switch 514 is opened. For example, if the coefficient value C is relatively small, this typically indicates that there is very little signal to equalize and therefore to preserve power and reduce excess noise, the filter section should be disabled by opening the switch 514.

FIG. 6 is a block diagram of a single tap of an alternative filter embodiment. In this embodiment, the shut down of the filter section, the update rate of the coefficient C, and the step-size s can be modified using other parameters. Data is inputted into delay register 600 of interval D seconds, where D is the symbol interval of the input data stream. A step-size s and an error e is multiplied at a multiplexer 604. The resultant of the multiplier 604 is inputted into a multiplier 602. The resultant of the multiplier 602 is inputted into with the output of coefficient C 608 at an adder 606. The resultant of the adder 606 is loaded into the coefficient register 608, if a switch 622 is closed. Also, the resultant of the multiplier 602 is inputted into an averager AV1 610. The AV1 610 takes an average of the coefficient adaptation values of the tap. A look-up table 612 includes step-size s values for the tap and an update rate r for the tap. If the value of the AV1 610 is great, then the update rate r from the look-up table 612 is high, and the rate of the coefficient changes and coefficient C 608 is updated at a greater rate. Also, should the value in the AV1 610 be high, the step-size s from the look-up table is high. A high value of average coefficient adaptation value indicates a dynamic echo. When a section contains more than one tap, the input to the lookup table 612 can be the maximum of the absolute value of all the averagers AV1 for all the taps in the section.

The step-size s is multiplied with the error e at multiplier 604. If the value in AV1 610 is low, then the update rate r from the look-up table is also low. Furthermore, the step-size s from the look-up table 612 is also low. An output of the coefficient C 608 is multiplied with the output from the delay logic 600 at multiplier 614. The resultant of the multiplier 614 is summed with other filter taps (not shown), if a switch 618 is closed. The output of the coefficient C 608 is also inputted into an averager AV2 616. The AV2 616 provides an average of the coefficient value 608 into a comparator 620. The compactor 620 compares the output of the averager AV2 616 with a threshold TRH. If the average AV2 value exceeds the threshold TRH, then the switch 618 is closed. When the section contains more than one tap, the input to the comparator 620 can be the maximum of the absolute values of all the averagers AV2 for all the taps in the section.

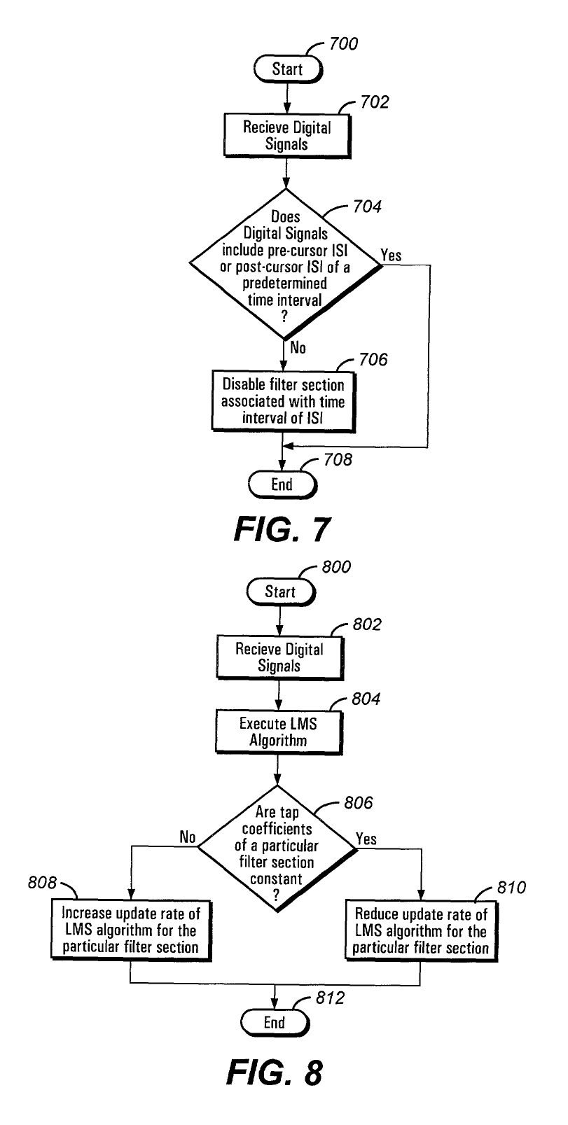

FIG. 7 is a flow chart for disabling a particular filter section of a DFE. A particular filter section of a feedforward and feedback filter can be disabled if a particular ISI associated with the filter section is not present. The method starts at step 700. The DFE receives digital signals at step 702. At step 704, if the digital signals include pre-cursor ISI or post-cursor ISI in a predetermined time period, then the method ends at step 708. If the received digital signals do not include pre-cursor ISI or post-cursor ISI of a predetermined time period, then at step 706 the filter section associated with the time interval of the ISI is disabled. Next, the method ends at step 708. Thus, if the DFE does not receive a particular pre-cursor or post-cursor ISI in a predetermined time interval associated with a filter section that would typically cancel that particular pre-cursor or post-cursor ISI, then the filter section is disabled. The disabling of a filter section generally reduces noise and power consumption.

FIG. 8 is a flow chart for revising an update rate r for a particular filter section using an LMS algorithm. For the filter sections that cancel an ISI that is constant, the update rate r used in the LMS algorithm can be reduced, thereby lowering excess noise, power consumption and improving convergence speed of the DFE. The method starts at step 800. A DFE receives digital signals at step 802. An LMS algorithm is executed for each of the filter sections of the feedforward and the feedback filters of the DFE at step 804. At step 806, if tap coefficients of a particular filter section is constant, then an update rate r used for the LMS algorithm is reduced for that particular filter section at step 810. If the tap coefficients of the particular filter section are not constant at step 806, then the update rate r of the LMS algorithm is increased for that particular filter section at step 808. The method ends at step 812. Thus, depending on the received pre-cursor or post-cursor ISI, the update rate r used in the LMS algorithm for that particular filter section can be modified, thereby reducing noise and power consumption and improving convergence speed of the DFE.

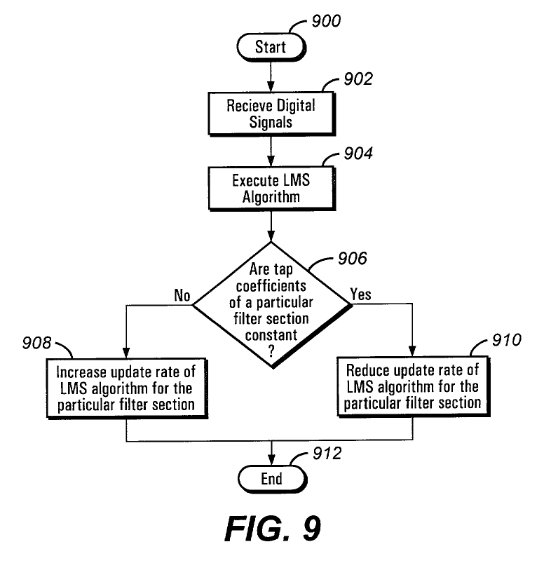

FIG. 9 is a flow chart for revising a step-size s in an LMS algorithm for a particular filter section. If a received digital signal receives more or less of a particular pre-cursor ISI or post-cursor ISI, a step-size s used in the LMS algorithm can be revised depending upon the presence of pre-cursor ISI or post-cursor ISI for that particular filter section of a feedforward or feedback filter of a DFE. The method starts at step 900. At step 902, the DFE receives digital signals. At step 904, an LMS algorithm is executed. At step 906, if the tap coefficients of a particular filter section is constant, then the step-size s used in the LMS algorithm is reduced for the particular filter section at step 910. If the tap coefficients of the particular filter section is not constant, then the step-size s used in the LMS algorithm is increased for the particular filter section at step 908. The method ends at step 912. Therefore, depending upon the presence of a particular pre-cursor or post-cursor ISI, the step-size s used in the LMS algorithm for the particular filter section is adjusted, thus improving convergence speed, and possibly lowering excess noise and power consumption of the DFE.

As can be appreciated by one skilled in the art, the use of the different step-size s for each filter section of a feedforward and feedback filter of a DFE can be implemented. Step-size s for each filter section can either be pre-determined or dynamically controlled. The use of different step-size s provide an elegant approach of canceling a particular ISI that may be more predominant in one time frame than another.

In addition, depending upon the environment, the update rate r for each filter section can be different. Should it be necessary to update the tap coefficients of the filter sections more rapidly as a result of the environment, the update rate r for that filter section can be high. Therefore, by using different step-size for each filter section, disabling the filter section if a particular ISI is not present, and applying different update rate r to each filter section, the convergence rate and dynamic tracking of the DFE is improved while lowering power consumption and excessive noise.

Thus, different control sections can control a particular parameter of the filter sections, such parameter includes enabling and disabling the filter section, coefficient tap values update rates, and step size values used for the LMS algorithm.

The foregoing disclosure and description of the invention are illustrative and explanatory thereof, and various changes in the size, shape, materials, components, circuit elements, wiring connections and contacts, as well as in the details of the illustrative circuitry and construction and method of operation may be made without departing from the spirit of the invention.

We claim:

1. A receiver, comprising:
a demodulator;
a decision feedback equalizer coupled to the demodulator, the decision feedback equalizer comprising:
a first digital filter having a plurality of first filter sections, each of the plurality of first filter sections with an independently controllable first parameter controlled by a corresponding one of a plurality of first control sections, each first filter sections having a plurality of first taps having first tap coefficients; and
a second digital filter.

2. The receiver of claim 1, wherein the second digital filter having a plurality of second filter sections, each of the plurality of second filter sections with an independently controllable second parameter controlled by a corresponding one of a plurality of second control sections, each second filter sections having a plurality of second taps having second tap coefficients.

3. The receiver of claim 1, wherein the first digital filter is a feedforward filter and the second digital filter is a feedback filter.

4. The receiver of claim 3, wherein the first parameter and the second parameter include step-sizes for an algorithm.

5. The receiver of claim 3, wherein the first parameter and the second parameter include update rates for an algorithm.

6. The receiver of claim 3, wherein the first parameter and the second parameter include enabling and disabling.

7. The receiver of claim 3, wherein the demodulator is a VSB demodulator.

8. The receiver of claim 7, wherein the VSB demodulator is an HDTV demodulator.

9. A decision feedback equalizer, comprising:
a first digital filter having a plurality of first filter sections, each of the plurality of first filter sections with an independently controllable first parameter controlled by a corresponding one of a plurality of first control sections, each first filter sections having a plurality of first taps having first tap coefficients; and
a second digital filter.

10. The receiver of claim 9, wherein the second digital filter having a plurality of second filter sections, each of the plurality of second filter sections with an independently controllable second parameter controlled by a corresponding one of a plurality of second control sections, each second filter sections having a plurality of second taps having second tap coefficients.

11. The decision feedback equalizer of claim 9, wherein the first digital filter is a feedforward filter and the second digital filter is a feedback filter.

12. The decision feedback equalizer of claim 10, wherein the first parameter and the second parameter include step-sizes for an algorithm.

13. The decision feedback equalizer of claim 10, wherein the first parameter and the second parameter include update rates for an algorithm.

14. The decision feedback equalizer of claim 10, wherein the first parameter and the second parameter include enabling and disabling.

15. The decision feedback equalizer of claim 9, wherein the first control sections are coupled to a processor.

16. The decision feedback equalizer of claim 9, wherein the first control sections are implemented in software.

17. The decision feedback equalizer of claim 11, wherein the feedforward filter cancels pre-cursor intersymbol interference.

18. The decision feedback equalizer of claim 11, wherein the feedback filter cancels post-cursor intersymbol interference.

19. The decision feedback equalizer of claim 9, wherein each of the plurality of first filter sections cancel a different time interval of pre-cursor intersymbol interference.

20. The decision feedback equalizer of claim 10, wherein each of the plurality of second filter sections cancel a different time interval of post-cursor intersymbol interference.

21. The decision feedback equalizer of claim 9, further comprising a look-up table.

22. The decision feedback equalizer of claim 21, wherein the look-up table provides a step-size value.

23. A method for updating tap coefficients of a plurality of filter sections of a decision feedback equalizer (DFE), comprising the steps of:
(1) receiving digital signals;
(2) ascertaining whether a particular intersymbol interference (ISI) within the digital signals exists in the plurality of filter sections; and
(3) disabling one of the plurality of filter sections if the particular ISI does not exist in one of the plurality of filter sections.

24. The method of claim 23, wherein the digital signals include HDTV signals.

25. A method for improving convergence speed, reducing excess noise and power consumption of a decision feedback equalizer (DFE) including a plurality of filter sections, comprising the steps of:
(1) receiving digital signals;
(2) executing a least mean square (LMS) algorithm;
(3) ascertaining whether a particular ISI within the digital signals exists in one of the plurality of filter sections; and
(4) revising the update rate of the LMS algorithm for one of the plurality of filter sections depending upon the presence of the particular ISI associated with one of the plurality of filter sections.

26. The method of claim 25, wherein the digital signals are HDTV signals.

27. A method for improving convergence speed, reducing excess noise and power of a decision feedback equalizer (DFE) including a plurality of filter sections, comprising the steps of:
(1) receiving digital signals;
(2) executing a least mean square (LMS) algorithm;
(3) ascertaining whether a particular ISI within the digital signals exists in one of the plurality of filter sections; and
(4) revising a step-size of the LMS algorithm for one of the plurality of filter sections depending upon the presence of the particular ISI associated with one of the plurality of filter sections.

28. The method of claim 27, wherein the digital signals are HDTV signals.

29. An apparatus for receiving terrestrial data, comprising:
a receiver, including:
a demodulator;
a decision feedback equalizer coupled to the demodulator, the decision feedback equalizer comprising:
a first digital filter having a plurality of first filter sections, each of the plurality of first filter sections with an independently controllable first parameter controlled by a corresponding one of a plurality of first control sections, each first filter sections having a plurality of first taps having first tap coefficients; and
a second digital filter; and
an antenna coupled to the receiver.

30. The apparatus of claim 29, wherein the second digital filter having a plurality of second filter sections, each of the plurality of second filter sections with an independently controllable second parameter controlled by a corresponding one of a plurality of second control sections, each second filter sections having a plurality of second taps having second tap coefficients.

31. The apparatus of claim 29, wherein the first digital filter is a feedforward filter and the second digital filter is a feedback filter.

32. The apparatus of claim 31, wherein the first parameter and the second parameter include step-sizes for an algorithm.

33. The apparatus of claim 31, wherein the first parameter and the second parameter include update rates for an algorithm.

34. The apparatus of claim 31, wherein the first parameter and the second parameter include enabling and disabling.

35. The apparatus of claim 31, wherein the demodulator is a VSB demodulator.

36. The apparatus of claim 35, wherein the VSB demodulator is an HDTV demodulator.
